(19) United States
(12) Patent Application Publication
(10) Pub. No.: US 2007/0152685 A1
(43) Pub. Date: Jul. 5, 2007

(54) A PROBE ARRAY STRUCTURE AND A METHOD OF MAKING A PROBE ARRAY STRUCTURE

(75) Inventors: Benjamin N. Eldridge, Danville, CA (US); Treliant Fang, Dublin, CA (US); John K. Gritters, Livermore, CA (US); Igor Y. Khandros, Orinda, CA (US); Dennis Lunyu Ma, San Jose, CA (US); Gaetan L. Mathieu, Varennes (CA)

Correspondence Address: N. KENNETH BURRASTON;KIRTON & MCCONKIE, P.O. BOX 45120, SALT LAKE CITY, UT, 84145-0120, US

(73) Assignee: FormFactor, Inc., Livermore, CA (US)

(21) Appl. No.: 11/306,574

(22) Filed: Jan. 3, 2006

(51) Int. Cl. G01R 31/02

(52) U.S. Cl. 324/754

(57) ABSTRACT

Probe array structures and methods of making probe array structures are disclosed. A plurality of electrically conductive elongate contact structures disposed on a first substrate can be provided. The contact structures can then be partially encased in a securing material such that ends of the contact structures extend from a surface of the securing material. The exposed portions of the contact structures can then be captured in a second substrate.

### BACKGROUND

An array of contact structures may be constructed and used in a variety of applications, including applications for probing another device. Probing an electronic device to test the electronic device is one example of such an application. For example, electrically conductive contact structures (or probes) may be configured in an array for contacting input and/or output terminals of the electronic device. The probes are pressed against the input and/or output terminals of the electronic device to be tested, forming electrical connections with those input and/or output terminals. Test signals are then input into the electronic device through some of the probes, and response data generated by the electronic device is read through others of the probes. A semiconductor die is an example of an electronic device that may be tested using an array of probes.

### SUMMARY

Exemplary embodiments of probe array structures and methods of making probe array structures are disclosed. In some exemplary embodiments, a plurality of electrically conductive elongate contact structures disposed on a first substrate is provided. The contact structures can then be partially encased in a securing material such that ends of the contact structures extend from a surface of the securing material. The exposed portions of the contact structures can then be captured in a second substrate.

### DESCRIPTION OF THE DRAWINGS

FIG. 1 illustrates a process for making a probe array structure according to some embodiments of the invention.

FIGS. 2A-2D illustrate formation of an exemplary probe array structure in accordance with the process of FIG. 1 according to some embodiments of the invention.

FIG. 3 shows a bottom view of the probe array structure of FIG. 2D.

FIGS. 4A-4H illustrate an example of 102 of the process of FIG. 1 according to some embodiments of the invention.

FIGS. 5A and 5B illustrate another example of 102 of the process of FIG. 1 according to some embodiments of the invention.

FIGS. 6A and 6B illustrate yet another example of 102 of the process of FIG. 1 according to some embodiments of the invention.

FIGS. 7A and 7B illustrate still another example of 102 of the process of FIG. 1 according to some embodiments of the invention.

FIGS. 8A and 8B illustrate yet another example of 102 of the process of FIG. 1 according to some embodiments of the invention.

FIGS. 9A-9E illustrate an example of 104 of the process of FIG. 1 according to some embodiments of the invention.

FIGS. 10A and 10B illustrate exemplary use of a mold for forming securing material around probes on a sacrificial substrate according to some embodiments of the invention.

FIG. 11 illustrates an example of 106 of the process of FIG. 1 according to some embodiments of the invention.

FIGS. 12A and 12B illustrate exemplary use of a mold for forming a probe substrate around portions of probes extending from a securing material according to some embodiments of the invention.

FIG. 13 illustrates an example of 108 of the process of FIG. 1 according to some embodiments of the invention.

FIGS. 14A and 14B illustrate an exemplary alternative method of attaching probes formed on a sacrificial substrate to a probe substrate according to some embodiments of the invention.

FIGS. 15A and 15B illustrate attachment of an exemplary probe array structures to an electronic component according to some embodiments of the invention.

FIG. 16A illustrates attachment of a plurality of exemplary probe array structures to an electronic component according to some embodiments of the invention.

FIG. 16B illustrates a bottom view of FIG. 16A.

FIG. 17 illustrates an exemplary system for testing dies of a semiconductor wafer according to some embodiments of the invention.

FIG. 18 illustrates an exemplary semiconductor wafer that may be tested in the system of FIG. 17 according to some embodiments of the invention.

FIG. 19 illustrates a simplified block and schematic diagram of an exemplary probe card assembly that may be used in the system of FIG. 17 according to some embodiments of the invention.

### DETAILED DESCRIPTION OF EXEMPLARY EMBODIMENTS

This specification describes exemplary embodiments and applications of the invention. The invention, however, is not limited to these exemplary embodiments and applications or to the manner in which the exemplary embodiments and applications operate or are described herein.

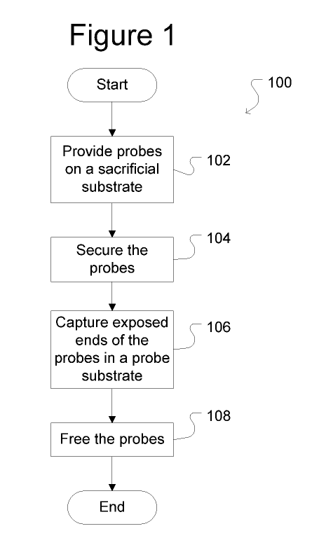

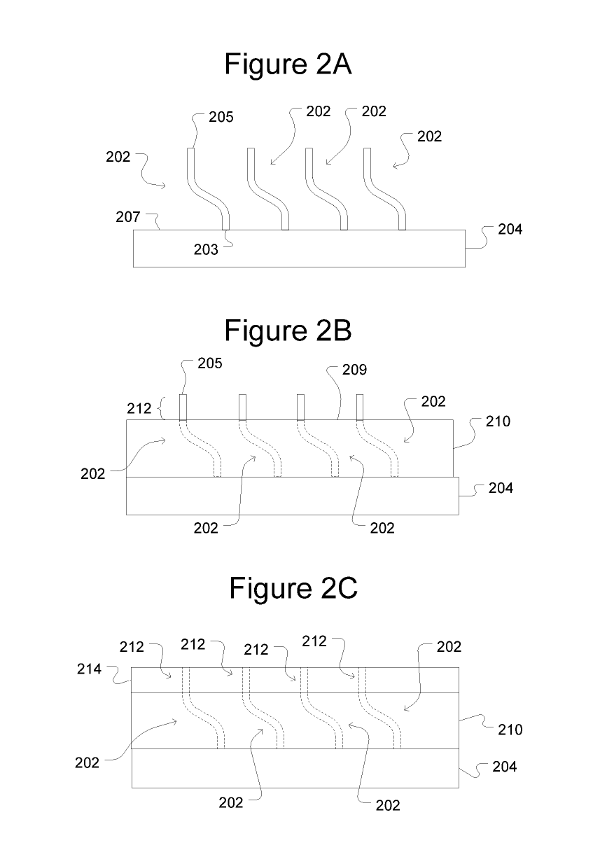

FIG. 1 illustrates a process 100 for making a probe array structure according to some embodiments of the invention, and FIGS. 2A-2D illustrate exemplary formation of a probe array structure 216 in accordance with process 100 of FIG. 1. Although process 100 is not limited to the examples shown in FIGS. 2A-2D, for illustration and ease of discussion, process 100 is discussed below with respect to the examples of FIGS. 2A-2D.

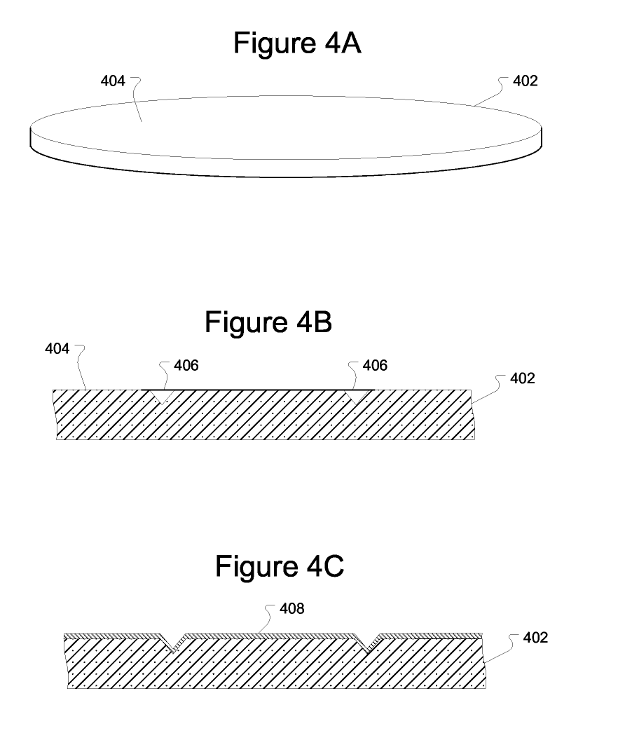

As shown in FIG. 1, a plurality of probes disposed on a sacrificial substrate is provided at 102. (As used herein, the term “sacrificial substrate” includes, without limitation, a removable substrate.) FIG. 2A shows a non-limiting example of a plurality of probes 202 on a sacrificial substrate 204 that may be provided in accordance with 102 of FIG. 1. As shown in FIG. 2A, probes 202 are attached to a surface 207 of sacrificial substrate 204. Each probe can include a contact tip 203 and a distal end 205. Probes 202 may be a resilient, conductive structure. Non-limiting examples of suitable probes 202 include composite structures formed of a core wire bonded to a conductive terminal (not shown) on a probe head assembly 108 that is over coated with a resilient material as described in U.S. Pat. No. 5,476,211, U.S. Pat. No. 5,917,707, and U.S. Pat. No. 6,336,269. Probes 202 may alternatively be lithographically formed structures, such as the spring elements disclosed in U.S. Pat. No. 5,994,152, U.S. Pat. No. 6,033,935, U.S. Pat. No. 6,255,126, U.S. Pat. No. 6,945,827, U.S. Patent Application Publication No. 2001/0044225, and U.S. Patent Application Publication No. 2004/0016119. Still other non-limiting examples of probes 202 are disclosed in U.S. Pat. No. 6,827,584, U.S. Pat. No. 6,640,432, U.S. Pat. No. 6,441,315, and U.S. Patent Application Publication No. 2001/0012739. Other nonlimiting examples of probes 202 include conductive pogo pins, bumps, studs, stamped springs, needles, buckling beams, etc. Five non-limiting examples of probes 202 are shown in FIGS. 4A through 8B and discussed below. Sacrificial substrate 204 may be any type of substrate that is suitable for supporting probes 202. Non-limiting examples of suitable sacrificial substrates 204 include a semiconductor wafer (e.g., a silicon wafer), a ceramic substrate, a printed circuit board substrate, a metal substrate, a substrate comprising an organic material, a substrate comprising an inorganic substrate, a metal substrate, a plastic substrate, etc.

Referring again to FIG. 1, the probes are secured in place (104). FIG. 2B illustrates an example in which a securing material 210 is formed around probes 202. In the example shown in FIG. 2B, the securing material 210 holds the contact tips 203, among other parts of the probes 202, in place. Distal portions 212 of the probes 202, however, are exposed and extend from a surface 209 of the securing material 210. As will be discussed in more detail below, one nonlimiting way of performing 104 of process 100 is to cast securing material 210 around entire portions of the probes 202 and then remove a portion of the securing material 210 to expose distal portions 212 of the probes 202. Securing material 210 can be any suitable material for holding probes 202 in position. Non-limiting examples of suitable materials include under fill materials, epoxy molding compounds, and glob-top materials.

Returning again to FIG. 1, at 106, exposed ends of the probes are captured in a probe substrate. FIG. 2C illustrates an example in which distal portions 212 of probes 202 are captured in a probe substrate 214. In the example shown in FIG. 2C, probe substrate 204 is formed by casting a flowable material around distal portions 212 of probes 202 and then hardening the flowable material into substrate 214.

At 108 of FIG. 1, the probes 202 are freed from the securing material 210 and the sacrificial substrate 204, leaving a probe array structure like, for example, the exemplary probe array structure 216 shown in FIG. 2D. As shown in FIG. 2D, the probe array structure 216 comprises probes 202 and probe substrate 214. The distal portions 212 of the probes 202 are secured within probe substrate 214, and contact tips 203 of the probes 202 extend away from the probe substrate 214.

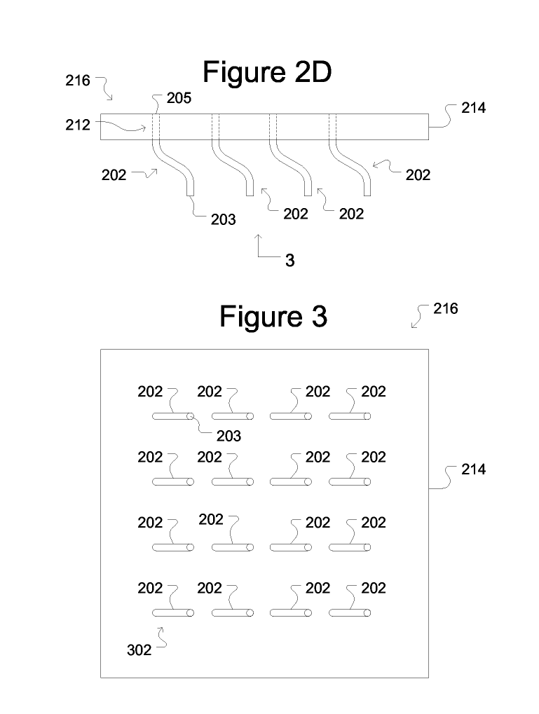

For ease of illustration and discussion, FIGS. 2A-2D show side views of probes 202, sacrificial substrate 204, securing material 210, and probe substrate 214. Although not readily apparent from the side views shown in FIGS. 2A-2D, the probes 202 may be disposed in a two-dimensional array. FIG. 3 shows a bottom view of the probe array structure of FIG. 2D, which shows probes 202 disposed in a four-by-four array 302. Of course, more or fewer probes 202 may be used and different sized and configured arrays are possible. Indeed, the number and layout of the probes is not important and any number and layout of probes may be used.

The sacrificial substrate 204 provided at 102 may be relatively large and may contain a relatively large number of probes 202. At any time during the process 100 of FIG. 1, the sacrificial substrate may be separated into smaller substrates (not shown) each containing a smaller number of probes 202. For example, if the sacrificial substrate 204 is a silicon wafer, the sacrificial substrate 204 may be diced using well know techniques for dicing silicon wafers. Such a separation of the sacrificial substrate 204 may occur after 102, in which case each smaller substrate may be individually processed in accordance with 104, 106, and 108. As another example, such a separation may occur after 104, in which case each smaller substrate can be individually processed in accordance with 106 and 108. Thus, for example, the structure shown in FIG. 2B may be separated into smaller substrates and the probes 202 on each smaller substrate captured in a probe substrate 214 as shown in FIG. 2C.

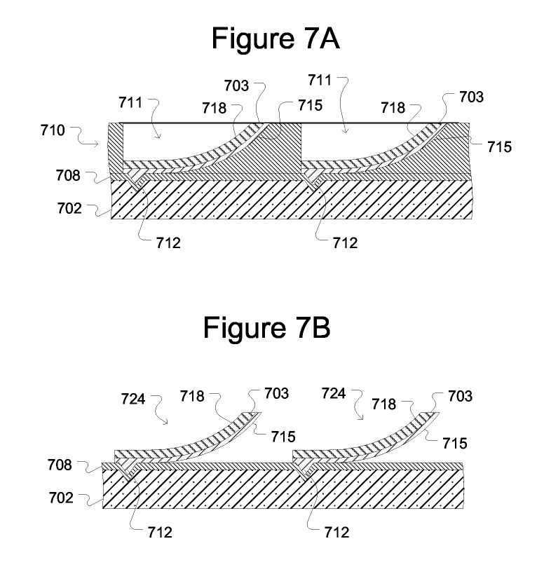

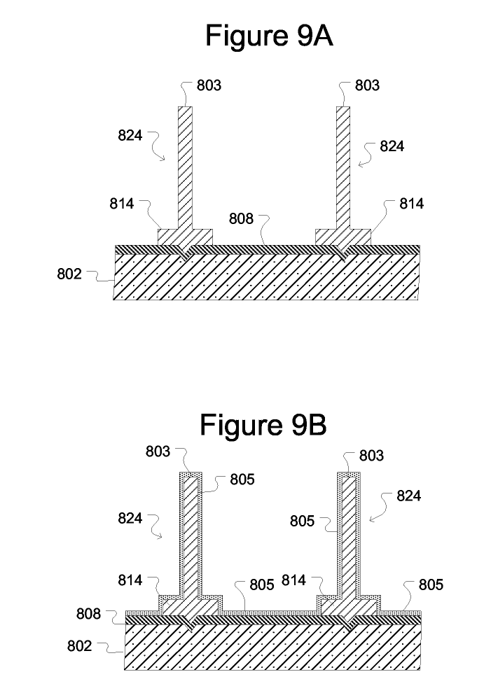

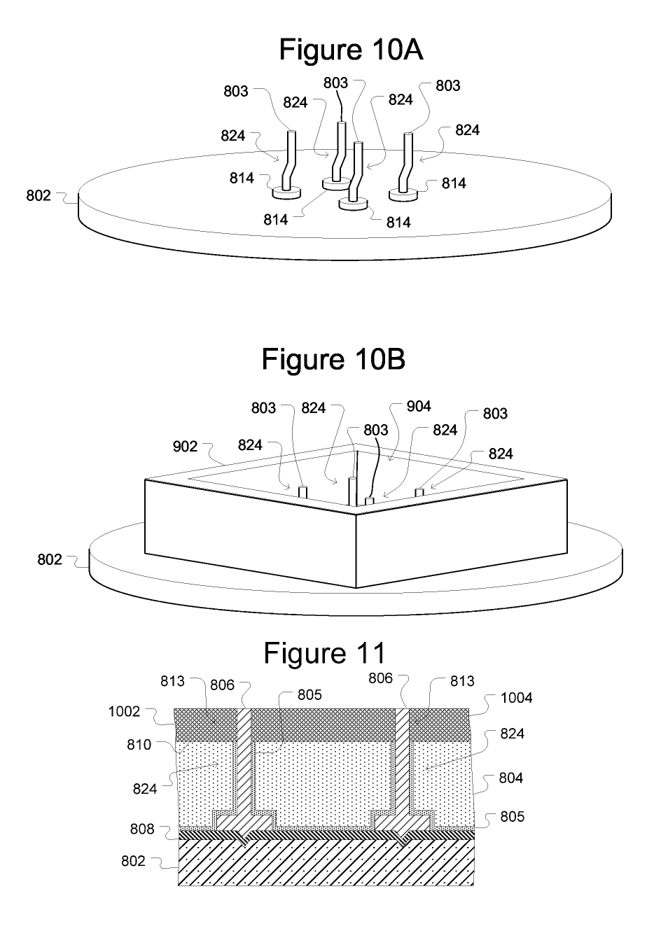

Process 100 of FIG. 1 thus illustrates a process for making a probe array structure comprising a plurality of probes disposed in any desired layout and secured to a probe substrate. FIGS. 4A-4H, FIGS. 5A and 5B, FIGS. 6A and 6B, FIGS. 7A and 7B, and FIGS. 8A and 8B illustrate detailed, nonlimiting examples of 102 of process 100 (FIG. 1)—providing probes on a sacrificial substrate. FIG. 9A illustrates generically the probes and sacrificial substrate provided in any of the examples shown in FIGS. 4A-8B, and FIGS. 9B-9E illustrate a detailed, nonlimiting example of further processing of those probes in accordance with 104 of process 100 of FIG. 1. FIGS. 11 and 13 illustrate detailed, nonlimiting examples of still further processing in accordance with 106 and 108 of process 100 of FIG. 1.

As previously mentioned, FIGS. 4A-4H, illustrate one example of 102 (providing probes on a sacrificial substrate) of process 100 of FIG. 1. As will be seen, in the example shown in FIGS. 4A-4H, a plurality of probes 424 are fabricated on sacrificial substrate 402.

FIG. 4A shows an exemplary sacrificial substrate 402 in the form of a semiconductor wafer having a surface 404. For example, sacrificial substrate 402 may be a silicon wafer. As shown in FIG. 4B, which shows a partial side cross-sectional view of the wafer 402 of FIG. 4A, pits 406 can be etched in surface 404 of sacrificial substrate 402. As will be seen, pits 406 can define tip features of the probes 424 that will be fabricated on the sacrificial substrate 402. The shape of pits 406 may be selected in accordance with the desired shape of the tip features of the probes 424. Non-limiting examples of tip shapes include pyramids, truncated pyramids, blades, bumps, etc. The pits 406 may be formed using any suitable means including without limitation chemical etching, stamping, carving, laser ablation, abrading, etc. Nonlimiting examples of suitable chemical etchants include oxides, including without limitation potassium oxide (KOH). Reactive ion etching techniques may also be used.

Pits 406 can be formed using lithographic techniques like those used to form integrated circuits in semiconductor materials. For example, sacrificial substrate 402 can be a silicon wafer, and a non-limiting exemplary process for forming pits 406 can be as follows: form an oxide layer on the wafer; apply a layer of masking material (e.g., a photo resist) over the oxide layer, and form openings in the masking material, exposing portions of the oxide layer that correspond to desired locations of pits 406; remove the exposed portions of the oxide layer (e.g., by etching with an etchant such as hydrogen fluoride), exposing selected portions of the wafer; remove the masking material; and etch pits 406 in the exposed portions of the wafer. Potassium hydroxide or other anisotropic etchants can be used to form tapered pits, like pits 406. Using the foregoing or other lithographic techniques, the positions of pits 406, and thus the resulting tip features of probes 424, can be positioned precisely, and the tip features may be formed in tight pitches. For example, pitches in which pits 406 are spaced 150 microns or less from one another are possible using such lithographic techniques.

Next, as shown in FIG. 4C, a release/seed layer 408 can be deposited over surface 404 of sacrificial substrate 402. Release/seed layer 408 can have, for example, two characteristics. First, the release/seed layer 408 can be easily removed, which, as will be seen, facilitates later removal of the probes 424 from the sacrificial substrate 402. Second, the release/seed layer 408 can be electrically conductive and, as will be seen, can function as an anode or cathode in an electroplating process by which material forming the probes 424 is electroplated onto the release/seed layer 408. Suitable materials for release/seed layer 408 include without limitation aluminum, copper, gold, titanium, tungsten, silver, and their alloys. Release/seed layer 408 may be deposited using any suitable method, including without limitation chemical vapor deposition, physical vapor deposition, sputter deposition, electroless plating, electron beam deposition, and thermal evaporation.

Alternatively, release/seed layer 408 may be replaced with multiple layers of material. For example, a release layer that is easily removed and thus facilitates removal of the probes from the sacrificial substrate 402 may be deposited on surface 404 and an electrically conductive seed layer may be deposited over the release layer.

As shown in FIG. 4D, a masking material 410 can be deposited over release/seed layer 408 and patterned to have openings 411. As will be seen, tips of the probes 424 can be fabricated in openings 411, which are therefore positioned on sacrificial substrate 402 and shaped in accordance with the desired positions and shapes of the tips 414 of the probes 424 as discussed above. The masking material 410 may be any material suitable for deposition on a sacrificial substrate 402 and patterning to form openings 411. For example, masking material 410 may be a photoresist material. A photoresist material may be deposited as a blanket layer over the entire surface of release/seed layer 408 and then selectively hardened using known techniques (e.g., exposure to light) everywhere except where the openings 411 are desired. Thereafter, the unhardened portions of the photoresist may be removed using known techniques, creating openings 411. Again, using photolithographic techniques like those used to form integrated circuits on semiconductor materials, openings 411 may be formed in precise locations.

Next, as shown in FIG. 4E, tip material can be deposited into openings 411 to form tips 414, each having a tip feature 412 defined by a pit 406 (see FIG. 4B). In the example shown in FIGS. 4A-4G, release/seed layer 408 is conductive so that the tip material may be electroplated onto the portions of the seed layer 408 that are exposed through openings 411. Alternatively, the tip material may be deposited using methods other than electroplating. Examples of such methods include chemical vapor deposition, physical vapor deposition, sputter deposition, electroless plating, electron beam deposition, and thermal evaporation. Of course, if the tip material is deposited other than by electroplating, release/seed layer 408 need not be electrically conductive. Regardless of how the tip material is deposited on release/seed layer 408, the tip material may be any suitable material including without limitation palladium, gold, rhodium, nickel, cobalt, silver, platinum, conductive nitrides, conductive carbides, tungsten, titanium, molybdenum, rhenium, indium, osmium, rhodium, copper, refractory metals, and their alloys including combinations of the foregoing. Although not shown in FIG. 4E, tips 414 may comprise a plurality of layers of the same or different materials.

As shown in FIG. 4F, probe bodies 416 can then be attached to tips 414. In the example shown in FIGS. 4A-4H, the probe bodies 416 are wires bonded at one end to tips 414. Such wires may be bonded to tips 414 using standard wire bonding techniques similar to those used to bond wires between bond pads of a semiconductor die and lead frames of a die package. As is known, such bonding techniques may involve pressing an end of a wire against a tip 414 while creating ultrasonic vibrations, which bonds the wire end to the tip 414. The foregoing process of pressing and vibrating may also include applying heat to the wire end and/or the tip 414. As is known, such techniques securely bond the wire to the tip 414. Such a bond is represented in FIG. 4E by bond portion 420. The wire is then spooled out and severed, forming wire portion 418 of probe body 416. The probe body 416 may be shaped by moving the spool as the wire is being spooled.

The wire used to form probe body 416 may be made of a relatively soft material that is readily bonded to tip 414 and shaped as the wire is spooled out. Nevertheless, the wire may comprise harder materials. Examples of suitable materials for wire include without limitation gold, aluminum, copper, solder, silver, platinum, lead, tin, indium, and their alloys including alloys with beryllium, cadmium, silicon and magnesium.

As shown in FIG. 4G, such a probe body 416 may be strengthened and/or other mechanical properties may be imparted to the probe body 416 by depositing an overcoat material 422 over the probe body 416. For example, overcoat material 422 may comprise a material that imparts resiliency, strength, and/or hardness to the probe body 416. As another example, the overcoat material 422 may have greater yield strength than the wire that forms probe body 416. By suitable selection of the overcoat material 422, the probes may have spring properties and thus be spring probes. Properties other than mechanical properties may be imparted to the wire body 416 by overcoat 422 (e.g., electrical conductivity, wearability, etc.) Suitable materials for overcoat 422 include without limitation copper, nickel, cobalt, tin, boron, phosphorous, chromium, tungsten, molybdenum, bismuth, indium, cesium, antimony, gold, silver, rhodium, palladium, platinum, ruthenium and their alloys

As also shown in FIG. 4G, the overcoat material 422 may also envelope bond portion 420 and thus further secure the bond portion 420 of probe body 416 to tip 414. Overcoat material 422 may thus strengthen the bond between probe body 416 and tip 414. Non-limiting examples of suitable overcoat materials include nickel, iron, cobalt, combinations of the foregoing, and alloys of the foregoing.

As shown in FIG. 4H, the masking material 410 may be removed, leaving a plurality of probes 424 on a sacrificial substrate 402. As shown in FIG. 4H, each probe 424 comprises a tip 414 and a probe body 416, and the probe body comprises a wire bonded to tip 414 and an overcoat material 422. As discussed above, tips 414 are attached to the sacrificial substrate 402, and distal ends 403 extend away from the sacrificial substrate 402.

Additional materials (not shown) may be deposited on the overcoat material 422 to enhance selected characteristics of the probes 424. For example, one or more materials (not shown) may be deposited on the overcoat material 422 to enhance the durability or wearability, the electrical conductivity, etc. of the probes 424.

U.S. Pat. No. 5,472,211, U.S. Pat. No. 5,917,707, U.S. Pat. No. 6,336,269, and U.S. Pat. No. 5,773,780 disclose additional information relevant to wiring bonding, over coating wires, and forming probe structures comprising an over coated wire.

FIGS. 4A-4H thus illustrate an exemplary method for providing a plurality of probes 424 attached to a sacrificial substrate 402 in accordance with 102 of process 100 of FIG. 1.

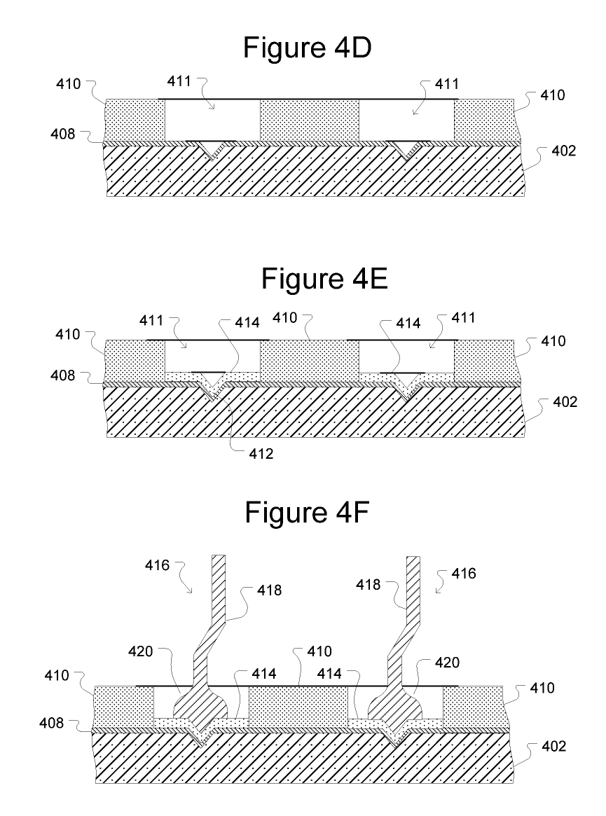

FIGS. 5A and 5B illustrate another exemplary method for providing a plurality of probes on a sacrificial substrate (102 of FIG. 1) according to some embodiments of the invention. As shown in FIG. 5B, this method yields probes 524 comprising lithographically formed tip 514, beam 518, and post 522 disposed on a sacrificial substrate 502. As illustrated in FIG. 5A, the tip 514, beam 518, and post 522 can be formed in multiple layers 510, 516, and 520 of masking materials disposed on a sacrificial substrate 502. The structure shown in FIG. 5A can be formed in a series of sequentially performed steps, which are discussed below.

The structure shown in FIG. 5A can be formed by starting with a sacrificial substrate 502, which may be the same as or similar to substrate 402 shown in FIG. 4A. Pits (not shown in FIG. 5A) defining tip features 512 of tip 514 can be formed in sacrificial substrate 502 in the same manner as pits 406 are formed in sacrificial substrate 402. Release/seed layer 508, which can be deposited over sacrificial substrate 502 as shown in FIG. 5A, may be the same as or similar to release/seed layer 408 and may be deposited in the same or similar manner as release/seed layer 408.

As shown in FIG. 5A, a first layer of masking material 510 can then be deposited over the release/seed layer 508 and patterned to have openings (not shown) defining tip 514. The first layer of masking material 510 may be similar to masking material 410 and may be deposited and patterned like masking material 410. Tip material can then be electroplated onto those portions of release/seed layer 508 exposed by the openings (not shown) in the first layer of masking material 510, forming tips 514. Once the tip material forming tips 514 is deposited in the openings (not shown) in the first layer of masking material 510, the exposed surfaces of the tip 514 and first layer of masking material 510 may be planarized.

A second layer of masking material 516 can then be deposited over the exposed surfaces of the tips 514 and the first layer of masking material 510 and patterned to have openings (not shown) defining beams 518. A first layer of conductive seed material 515 is deposited in the openings (not shown) in the second layer of masking material 516. The first seed material 515, which is electrically connected to the release/seed layer 508 through tips 514, can function as a cathode or anode in a plating process and allows beam material forming beams 518 to be electroplated into the openings (not shown) in the second layer of masking material 516. After the beam material is deposited into the openings (not shown) in the second layer of masking material 516 forming beams 518, the exposed surfaces of the beams 518 and second layer of masking material 516 may be planarized.

A third layer of masking material 520 can then be deposited over the exposed surfaces of the beams 518 and the second layer of masking material 516 and patterned to have openings (not shown) defining posts 522. A second layer of conductive seed material 517 can be deposited in the openings (not shown) in the third layer of masking material 520. The second seed material 517 can be electrically connected to the release/seed layer 508 through tips 514, first seed layer 515, and beams 518 and function as a cathode or anode in a plating process and allows post material that forms posts 522 to be electroplated into the openings (not shown) in the third layer of masking material 520. After the post material is deposited into the openings (not shown) in the third layer of masking material 520 forming posts 522, the exposed surfaces of the posts 522 and third layer of masking material 520 may be planarized.

The first layer of masking material 510, the second layer of masking material 516, and the third layer of masking material 520 may be similar to the masking material 410 discussed above with respect to FIGS. 4A-4H and may be deposited and patterned using the same techniques as discussed above with respect to masking material 410. First seed layer 515 and second seed layer 517 may be any electrically conductive material and may be deposited using any of the techniques discussed above with respect to release/seed layer 408. The tip material, beam material, and post material that forms tips 514, beams 518, and posts 522 may be formed of any of the materials discussed above with respect to tip 414 in FIGS. 4A-4H. In addition, those materials may be deposited other than by electroplating using any of the alternative deposition methods identified above with respect to tip 414. Moreover, any one or more of the tips 514, beams 516, or posts 522 may comprise multiple materials deposited in multiples.

As shown in FIG. 5B, the first layer of masking material 510, the second layer of masking material 516, and the third layer of masking material 520 can be removed from sacrificial substrate 502, leaving probes 524 on a sacrificial substrate 502. The process illustrated in FIGS. 5A and 5B thus produces a plurality of probes 524—each comprising a tip 514 having a tip feature 512, a beam 518, and a post 522—disposed on a sacrificial substrate 502. As shown, tips 514 can be attached to the sacrificial substrate 502, and distal ends 503 can extend away from the sacrificial substrate 502.

Probe structures 524 may be generally similar to probe structures disclosed in U.S. Pat. No. 6,520,778 and U.S. Pat. No. 6,268,015, both of which include additional information regarding the construction of such probe structures.

FIGS. 5A and 5B thus illustrate another exemplary method for providing a plurality of probes 524 attached to a sacrificial substrate 502 in accordance with 102 of process 100 of FIG. 1 according to some embodiments of the invention.

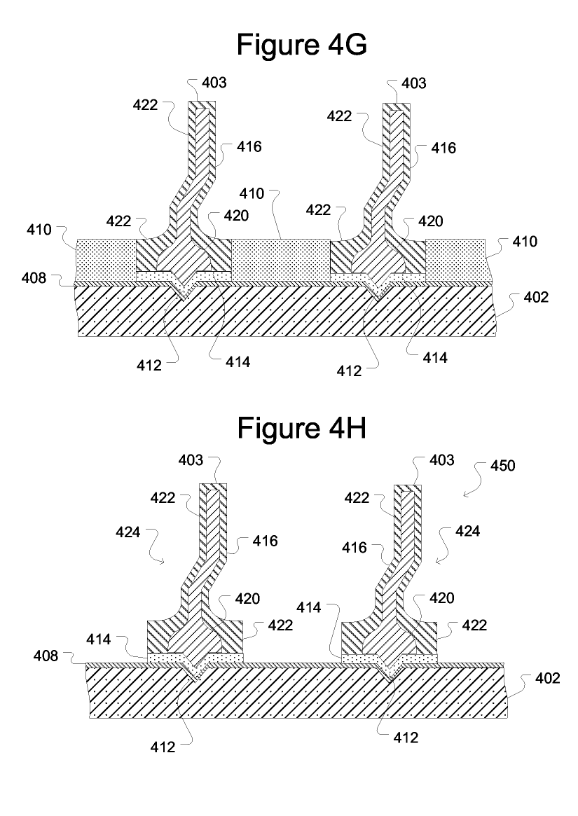

FIGS. 6A and 6B illustrate yet another exemplary method for providing a plurality of probes on a sacrificial substrate (102 of FIG. 1) according to some embodiments of the invention. As shown in FIG. 6B, this method can yield probes 624 disposed on sacrificial substrate 602. The probes 624 include a tip 614 and a beam 618 similar to tip 514 and beam 518 of FIGS. 5A and 5B. Moreover, tips 614 and beams 618 may be formed in the same manner in which tips 514 and beams 518 are formed. That is, pits (not shown) can be etched in a sacrificial substrate 602, which can then be covered with a release/seed layer 608. Tips 614 can be formed by depositing tip material in openings (not shown) in a first masking layer 610, and beams 618 can be formed by depositing beam material onto a seed layer 615 in openings (not shown) in a second masking layer 616 generally as discussed above with respect to FIGS. 5A and 5B. Sacrificial substrate 602 may be the same as or similar to sacrificial substrate 502; release/seed layer 608 may be the same as or similar to release/seed layer 508; first masking layer 610 and second masking layer 616 may be the same as or similar to first masking layer 510 and second masking layer 516; seed layer 615 may be the same as or similar to seed layer 515; and tips 614 and beams 618 may be the same as or similar to tips 514 and beams 518.

As shown in FIG. 6A, however, wires can be bonded to beam 518 forming wire columns 622. The wires may be bonded to the beam 518 using standard wire bonding techniques, as discussed above. Although not shown, the wire columns 622 may be over coated with one or more materials to enhance characteristics of the columns 622 such as electrical conductivity, yield strength, resilience, hardness, wearability, etc. Although FIG. 6A illustrates two wire columns, one wire column or three or more wire columns can be used.

As shown in FIG. 6B, the first layer of masking material 610 and the second layer of masking material 616 can be removed from sacrificial substrate 602, leaving probes 624 on sacrificial substrate 602. The process illustrated in FIGS. 6A and 6B thus can produce a plurality of probes 624—each comprising a tip 614 with tip feature 612, a beam 618, and a wire columns 622—disposed on a sacrificial substrate 602. As shown, tips 614 can be attached to the sacrificial substrate 602, and distal ends 603 can extend away from the sacrificial substrate 602.

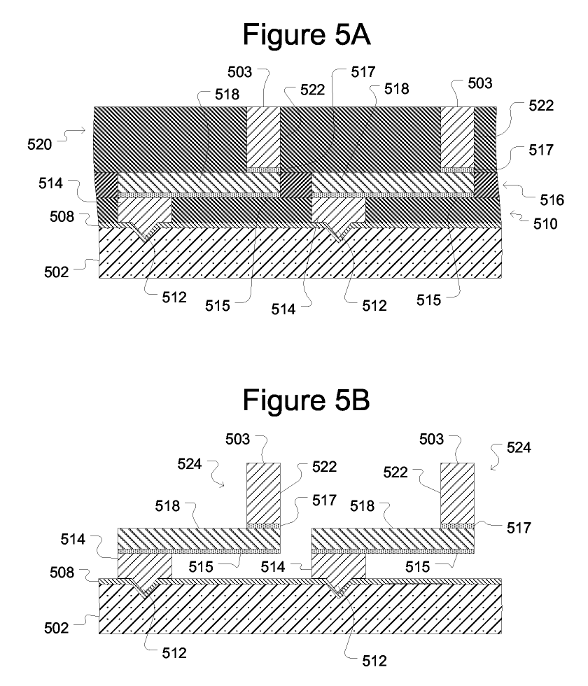

Probe structures 624 may be generally similar to probe structures disclosed in U.S. Published Patent Application No. 2001/0044225 and in FIGS. 7G and 7H of U.S. Pat. No. 5,994,152, both of which include additional information regarding the construction of such probe structures.

FIGS. 7A and 7B illustrate still another exemplary method for providing a plurality of probes on a sacrificial substrate (102 of FIG. 1) according to some embodiments of the invention. Sacrificial substrate 702 may be the same as or similar to sacrificial substrate 402 of FIGS. 4A-4H. Pits (not shown) defining tip features 712 can be formed in sacrificial substrate 702 in the same manner as pits 406. Release/seed layer 708, which is deposited over sacrificial substrate 702 as shown in FIG. 7A, may be the same as or similar to and may be deposited in the same or similar manner as release/seed layer 408.

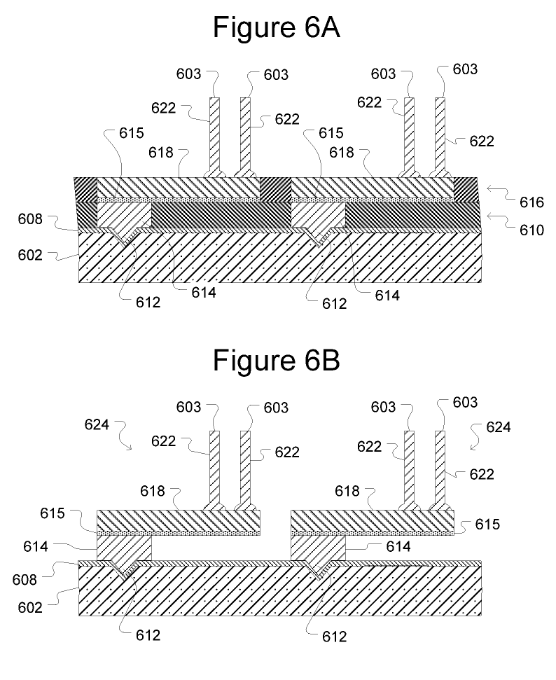

As shown in FIG. 7A, a layer of masking material 710—which may be the same as or similar to masking material 410—is deposited over the release/seed layer 708 and patterned to have openings 711, which can define the shape of probes 724 (see FIG. 7B). The shape of openings 711 may be formed in any number of ways. For example, a shaped stamping tool may be used to stamp openings 711 into masking material 710 as shown in FIGS. 2A-2D of U.S. Published Patent Application No. 2001/0044225, the meniscus of a fluid deposited into openings 711 may be used to define the shape of the openings 711 as shown in FIGS. 8A-8F of U.S. Published Patent Application No. 2001/0044225, or any of the various techniques disclosed in U.S. patent application Ser. No. 09/539,287 may be used to define the shape of openings 711. A layer of conductive material 715 can be deposited within openings 711. Material 715 is electrically connected to release/seed layer 708 and therefore may function as the cathode or anode in a plating process. Material 715 may be the same as or similar to seed layers 515 or 517 in FIGS. 5A and 5B and may be similarly deposited. Probe material 718 may then be electroplated onto layer 715. As can be seen in FIGS. 7A and 7B, material 715 also includes the tip features 712 of probes 724. Material 715 may therefore comprise a material suitable for a contact tip (e.g., the materials identified above with respect to tip 414).

As shown in FIG. 7B, the masking material 710 can be removed from sacrificial substrate 702, leaving probes 724 on sacrificial substrate 702. The process illustrated in FIGS. 7A and 7B thus produces a plurality of probes 724 disposed on a sacrificial substrate 702. As shown, tips 714 can be attached to the sacrificial substrate 702, and distal ends 703 extend away from the sacrificial substrate 702.

Probe structures 724 may be generally similar to probe structures disclosed in any of the following U.S. patents or patent applications, each of which includes additional information regarding the construction of such probe structures: U.S. Pat. No. 6,064,213, U.S. Pat. No. 6,713,374, U.S. Published Patent Application No. 2001/0044225, and U.S. patent application Ser. No. 09/539,287. Probe structures, like probe structures 724, can alternatively be formed as generally disclosed in U.S. Pat. No. 6,827,584 and U.S. Pat. No. 6,640,432.

FIGS. 8A and 8B illustrate still another exemplary method for providing a plurality of probes on a sacrificial substrate (102 of FIG. 1) according to some embodiments of the invention. As shown in FIG. 8A, a plurality of loose probes 774 can be provided. Probes 774 can be fabricated in any suitable manner. For example, probes 774 can be fabricated as described in U.S. Patent Application Publication 2004/0016119. Other non-limiting examples of fabricating probes 774 include stamping or cutting probes 774 from a sheet of metal, casting probes 774 in a mold, etc. As shown, each probe 774 can comprise a tip 762 and a distal end 753. As shown in FIG. 8B, tips 762 of probes 774 can be secured in holes (not shown) in an alignment substrate (e.g., a semiconductor wafer, a metal plate, an organic or inorganic substrate, etc. into which holes (not shown) for receiving tips 762 have been created), which can be a sacrificial substrate. Tips 762 can be secured in the holes (not shown) in the alignment substrate in any manner. For example, tips 762 can be secured in the holes (not shown) in the alignment substrate 752 using an adhesive, solder, magnetic attraction, friction, gravity, etc. Probes 774 can be released from alignment substrate 752 in any suitable manner.

As discussed above with respect to probes 424, additional materials (not shown) may be deposited on any of probes 524, 624, 724, and 774 to enhance selected characteristics of the probes, such as strength, resilience, durability, wearability, electrical conductivity, etc.

FIGS. 4A-4G, 5A and 5B, 6A and 6B, 7A and 7B, and 8A and 8B thus illustrate various examples of 102 of FIG. 1 (providing probes on a sacrificial substrate). Thereafter, probes 424 formed on sacrificial substrate 402, probes 524 formed on sacrificial substrate 502, probes 624 formed on sacrificial substrate 602, probes 724 formed on sacrificial substrate 702, or probes 774 attached to alignment substrate 752 may be processed in accordance with 104, 106, and 108 of FIG. 1. FIGS. 9A-9E illustrate a detailed example of further processing in accordance with 104 of FIG. 1: securing the probes.

FIG. 9A is a generic representation of any of probes 424, 524, 624, 724, or 774 fabricated on sacrificial substrates 402, 502, 602, or 702 or attached to an alignment substrate 752 (which can be a sacrificial substrate) as shown in FIGS. 4G, 5B, 6B, 7B, and 8B. That is, in FIG. 9A, probes 824 are generic representations of any of probes 424, 524, 624, 724, 774; sacrificial substrate 802 is a generic representation of any of sacrificial substrates 402, 502, 602, or 702 or alignment substrate 752; and release/seed layer 808 is a generic representation of any of release/seed layers 408, 508, 608, or 708. Release/seed layer 808 is optional. For example, the example shown in FIGS. 8A and 8B does show a seed/release layer. Moreover, distal end 803 is generic representative of any of distal ends 403, 503, 603, 703, 753 and tip 814 is representative of any of tips 414, 514, 614, 714, 762, or the potion of material 715 attached to sacrificial substrate 702 in FIG. 7B.

As shown in FIG. 9B, probes 824 and sacrificial substrate 802 can optionally be coated with a protective coating 805, which may be any coating suitable for protecting probes 824 from a securing material 804 shown in FIG. 9C. Examples of such coatings include without limitation parylene.

As shown in FIG. 9C, a securing material 804 (which can be like securing material 210) can then be cast on sacrificial substrate 802, enveloping probes 824. Securing material 804 may be any material suitable for forming around probes 824. For example, securing material 804 may be a material that is applied to sacrificial substrate 802 in a liquid or flowable state and thereafter hardens into a solid state. Examples of suitable securing materials 804 include without limitation acrylics, under fill materials, epoxy molding compounds, and glob-top materials.

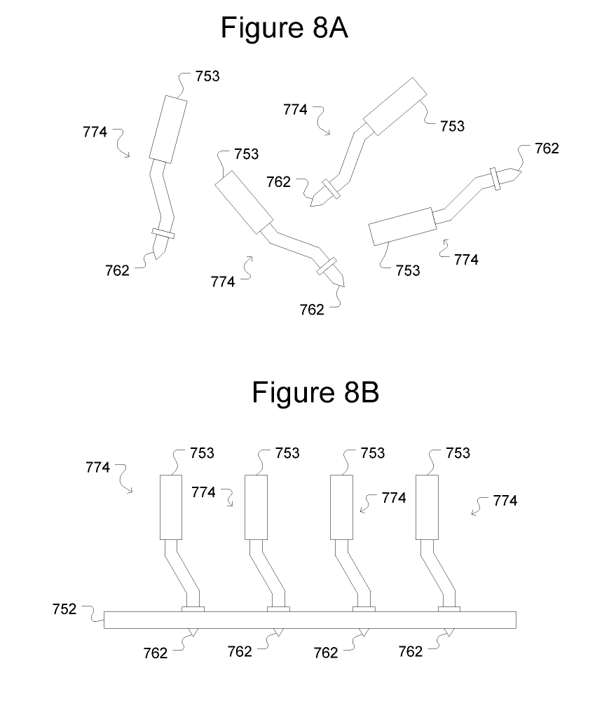

Securing material 804 may be applied in any suitable manner. FIGS. 10A and 10B illustrate one exemplary way of applying securing material 804 according to some embodiments of the invention. FIG. 10A shows an elevated, perspective view of sacrificial substrate 802 and an array of four probes 824. A mold 902 is placed on sacrificial substrate 802 such that probes 824 are in an opening 904 of mold 902 as shown in FIG. 10B. The securing material 804 may then be poured into opening 904. Mold 902 can then be held in place until the securing material 804 hardens, after which the mold 902 may be removed. Rather than pour securing material 804 into opening 904, securing material 804 may be injected into or transferred into opening 904 using standard injection molding or transfer molding techniques. Other molding techniques may alternatively be used to form securing material 804 around probes 824.

Returning to the process illustrated by FIGS. 9A-9E, as shown in FIG. 9D, the securing material 804 can be lapped, ground, or otherwise removed to expose finished ends 806 of probes 824. Portions of the probes 824 may also be lapped, grinded, or otherwise planarized to planarize finished ends 806 of probes 824 and surface 808 of securing material 804. Then, as shown in FIG. 9E, an upper portion 890 of securing material 804 and portions of coating 805 can be removed to expose portions 813 of probes 824. The upper portion 890 of securing material 804 can be removed by any suitable means including without limitation etching. For example, a wet etching process may be used to remove upper portion 890 of securing material 804. For example, potassium hydroxide (KOH) can be used as an etchant. For example, 5-20% KOH in ethyleneglycol at a temperature in the range of 50-200 degrees centigrade can be used as an etchant. Other removal processes can alternatively be used including without limitation dry etching, such as with reactive gases, laser ablation, etc. The amount of securing material 804 etched away may be controlled by controlling the amount of etching solvent applied to the securing material 804. As will be seen, the amount of securing material 804 removed may correspond to the desired thickness of a probe substrate that will be formed on surface 810 of securing material 804.

The structure shown in FIG. 9E thus represents processing of the structure shown in FIG. 9A in accordance with 104 of FIG. 1. FIGS. 11 and 13 illustrate exemplary further processing of the structure shown in FIG. 9E in accordance with 106 and 108 of FIG. 1.

As shown in FIG. 11, a moldable material 1002 can be formed on surface 810 of securing material 804 and around the exposed portions 813 of probes 824. The moldable material 1002 may be a liquid or flowable material that is molded around the exposed portions 813 of probes 824 and then hardened to become a probe substrate 1002′. The moldable material 1002 thus captures the exposed portions 813 of probes 824, attaching probes 824 to probe substrate 1002′. An upper surface of probe substrate 1002′ may be lapped, grinded, or otherwise planarized to, among other things, ensure that finished ends 806 of probes 424 are exposed.

The moldable material 1002 may be any material suitable for forming around the exposed portions 813 of probes 824. For example, the moldable material 1002 can be an acrylic material, an epoxy (filled or unfilled), an epoxy resin, a low melting point glass, an organic material, an inorganic material, etc. One non-limiting example of an epoxy resin that can be used as moldable material 1002 is an alkali-etchable toughened UV-curable epoxy resin. Such an alkali—etchable toughened UV-curable epoxy resin can comprise a two part liquid system: one part can be anhydride/photo initiator, and the other part can be an epoxy/toughener/acrylate mixture.

In another non-limiting example, the two-part liquid system can comprise a part A and a part B, wherein part A and part B can be as follows:
Part A:
   A component that renders the resulting compound (the mixture of Part A and Part B) base etchable (that is, etchable using a base solution (e.g., potassium hydroxide (KOH) in water or an organic solvent, such as ethyleneglycol)). Examples of such components include without limitation hexahydromethyl phthalic anhydride (HMPA), tetrahydorphthalic anhydride, phthalic anhydride, and nadic anhydride.
   An epoxy curing agent such as 2-ethyl-4-methylimidazole (EMI), alkylimidazoles, or piperidines, or any other agent that allows the resulting compound to be cured thermally; and
   A free-radical photoinitiator that allows room temperature gelling of the resulting compound by exposure to ultraviolet light. Examples of such photoinitiators include any radical-generating compound, whether thermal or photo reactive. One such example is 2,2-dimethoxy-2-phenylacetophenone.
Part B:
   A body component forming a body of the resulting compound. Examples of such components include without limitation a bisphenol A diepoxide (e.g., available from Dow Chemicals, Inc. under the trade name Dow Epoxy Resin #383), any aromatic diepoxide (e.g., BisA, BisF), any thermally-curable resin (e.g., triallyloxy-1,3,5-triazine or triallyl-1,3,5-triazone-trione).
   A component to toughen the body component and prevent cracking of the resulting compound, for example, during thermal cure and etching. This component can also be base etchable. Examples of such components include without limitation a polyol toughener available from Union-Carbide, Inc. under the trade name TONE2221 or any other epoxy toughener.
   A photosensitive component that polymerizes in the presence of a photoinitator and ultraviolet light. Non-limiting examples of such components include photoactive materials such as acrylates, methacrylates, and mercaptans. For example, hydroxypropyl acrylate (HPA) or pentaerythritol tetrakis(3-mercaptopropionate) can be used.

In one non-limiting example, the compound is a mixture of approximately three parts part A and approximately four parts part B by weight, where Part A and Part B are as follows:
Part A:
   approximately 88% by weight hexahydromethyl phthalic anhydride (HMPA);
   approximately 8% by weight 2-ethyl-4-methylimidazole (EMI); and
   approximately 4% by weight 2,2-dimethoxy-2-phenylacetophenone.
Pat B:
   approximately 41% by weight Dow Epoxy Resin #383;
   approximately 29% by weight TONE2221; and
   approximately 30% by weight hydroxypropyl acrylate (HPA).
      Where: 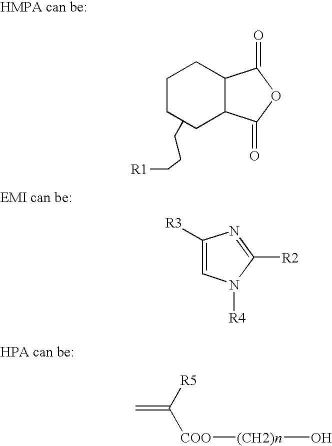
      and:
   R1 can be CH3, H, C1 to C20 alkyl, or C═C double bond
   R2 can be C2H5, H, C1 to C20 alkyl,
   R3 can be CH3, H, C1 to C20 alkyl,
   R4 can be H, C1 to C20 alkyl,
   R5 can be H, C1 to C5 alkyl, and
   n can be 2 to 10.
      The foregoing compound can be polymerized (gelled) by exposure to ultraviolet light (e.g., about 500 milijoules) and thermally cured (e.g., by being heated to about 70 degrees centigrade for about twelve hours).

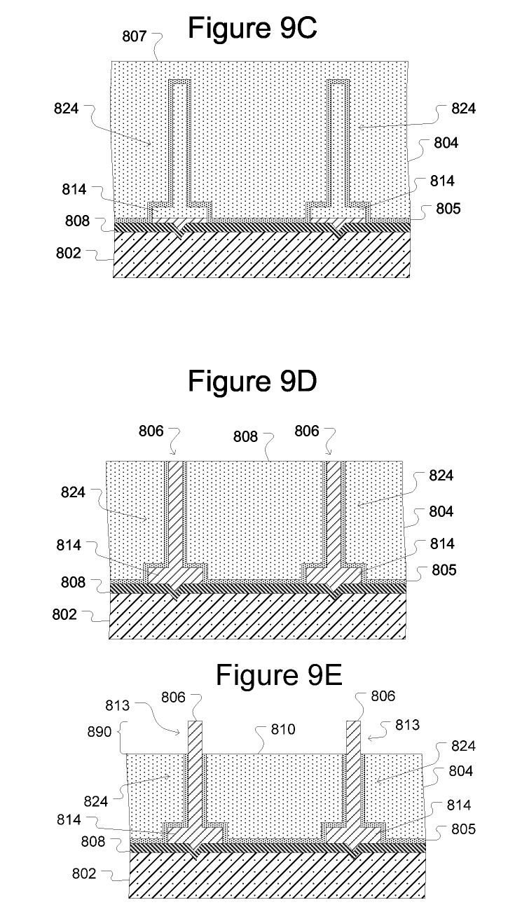

FIGS. 12A and 12B illustrate an exemplary mold 1102 that may be used to form moldable material 1002 around exposed portions 813 of probes 824 according to some embodiments of the invention. FIG. 12A shows an elevated perspective view of the structure of FIG. 9E, which shows securing material 804 formed around exposed portions 813 of probes 824. As shown in FIG. 12B, a mold 1102 can be placed on surface 810 of securing material 804. An opening 1104 in the mold 1102 can then be filled with moldable material 1002. For example, the opening 1104 may be filled with the moldable material 1002, after which the moldable material can be compressed and smoothed to be even with the upper rim 1106 of mold 1102. Alternatively, mold 1102 may be fitted with a top cover (not shown) and moldable material 1002 may be injected into the mold 1102 through inlets (not shown) using well known injection molding techniques. As another example, the moldable material 1002 may be transfer molded into a mold like 1102 or may be spin cast onto surface 810. Other methods of forming moldable material 1002 on surface 810 of securing material 804 may also be used.

Once moldable material 1002 has hardened into probe substrate 1002′ (e.g., by gelling and curing the moldable material 1002 as described above), the probes 824 may be released from the securing material 804 and the sacrificial substrate 802 as shown in FIG. 13, which illustrates an example of 108 of FIG. 1. Probes 824 may be released from sacrificial substrate 802 by removing (e.g., by etching or dissolving) release/seed layer 808. Etching materials or solvents may be used to dissolve or otherwise remove securing material 804 and protective coating 805. Before or after releasing the probes 824 from sacrificial substrate 802, the moldable material 1002 can be grinded, lapped, or otherwise smoothed.

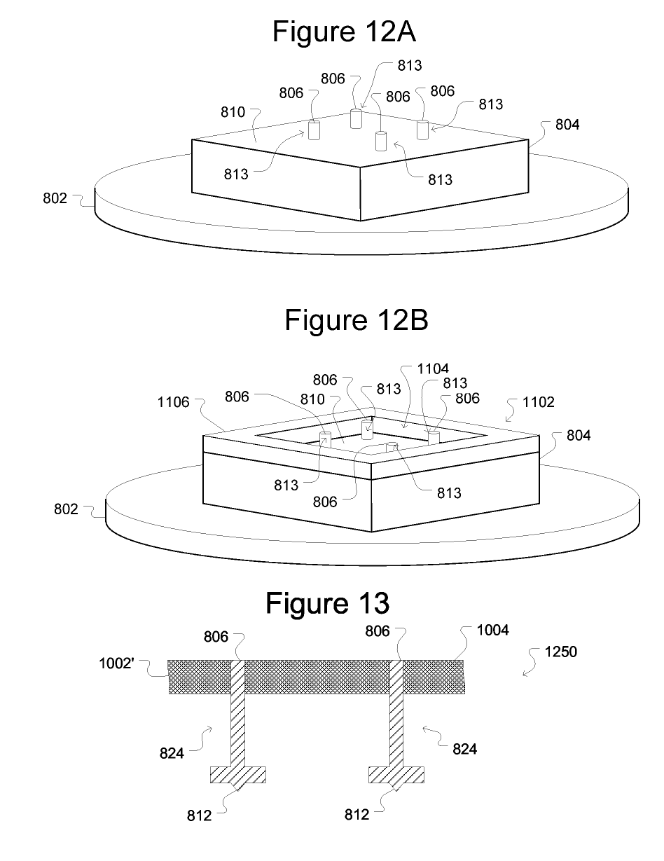

FIGS. 14A and 14B illustrate an alternative to 104 and 106 of FIG. 1 according to some embodiments of the invention. FIG. 14A illustrates a generic representation of probes 1324 on a sacrificial substrate 1302 such as may be provided in 102 of FIG. 1. For example, probes 1324 may be any of probes 202, 424, 524, 624, 724, 774, or 824, and sacrificial substrate may be any of sacrificial substrates 204, 402, 502, 602, 702, or 802 or alignment substrate 752. As shown in FIG. 14A, rather than further process the probes 1324 in accordance with 104 and 106 of FIG. 1, distal ends 1305 of probes 1324 can be inserted into openings 1322 in a probe substrate 1320. As shown in FIG. 14B, probes 1324 may then be soldered 1310 or otherwise attached in place to probe substrate 1320, after which probes 1324 are released from sacrificial substrate 1302 in accordance with 08 of FIG. 1.

In the example shown in FIGS. 14A and 14B, openings 1322 are larger than the distal ends 1305 of probes 1324, and the ends 1305 of probes 1324 are accordingly soldered, brazed, or otherwise secured to the probe substrate 1320. As an alternative, openings 1322 may be made smaller than probes 1324, and the probes 1324 may be attached to the probe substrate 1320 by heating the probe substrate 1320 to expand the openings 1322 until they are larger than the probes 1324, inserting distal ends 1305 of the probes 1324 into openings 1322 as generally shown in FIG. 14A, and then allowing the probe substrate 1320 to cool. As the probe substrate 1320 cools, the openings 1322 contract generally to their original size (smaller than the probes). The probes 1324 may thus be captured by the probe substrate 1320.

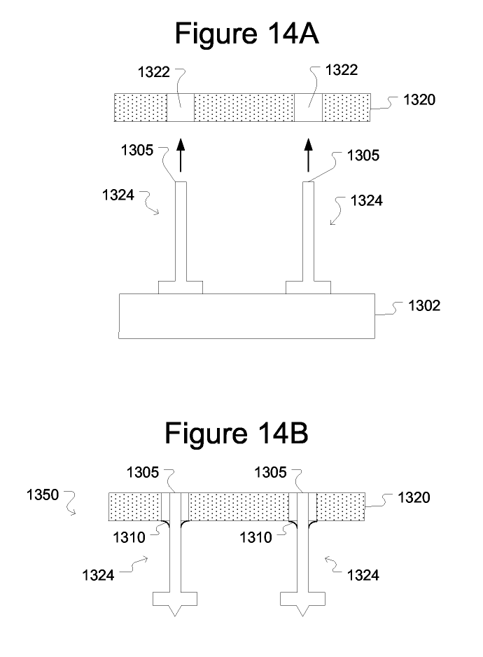

Once an array of probes secured to a probe substrate is fabricated using any of the techniques discussed above, the array of probe and probe substrate may be utilized by themselves or may be attached to another component. FIGS. 15A and 15B illustrate an example in which a probe array structure 1450 is attached to another electronic component 1422 according to some embodiments of the invention.

In FIG. 15A, probe array structure 1450 can include a plurality of probes 1424 (two are shown but more may be included) attached to a probe substrate 1420. The probe array structure 1450 may be made using any of the techniques discussed above. Thus, for example, probe array structure 1450 may be the same as probe array structure 216 of FIG. 2D, probe array structure 1250 of FIG. 13, or probe array structure 1350 of FIG. 14B. As shown in FIG. 15A, distal ends 1403 of probes 1424 may be soldered 1426 to terminals 1428 of electronic component 1422. Probes 1424 thus provide electrically conductive paths from terminals 1428 of electronic component 1422 through solder 1426 and through probes 1424 to the tip features 1412. Terminals 1428 may be electrically connected through conductors (not shown) disposed within electronic component 1422 to other terminals or electronic elements (not shown) on electronic component 1422. Conductive adhering materials other than solder 1426 may be used (e.g., brazing materials) to attach the probe array structure 1450 to the electronic component 1422 and electrically connect distal ends 1403 of probes 1424 to terminals 1428 of electronic component 1422.

To further secure probe substrate 1420 to electronic component 1422, and to protect and strengthen probe substrate 1420, an under-fill material 1432 may be disposed between probe substrate 1420 and electronic component 1422 as shown in FIG. 15B. Electronic component 1422 may be any electronic component including without limitation a component of a test apparatus in which electronic component 1422 is part of an interface to a tester (not shown) for controlling testing of an electronic device (not shown) and probes 1424 are configured to contact input and/or output terminals of the electronic device being tested.

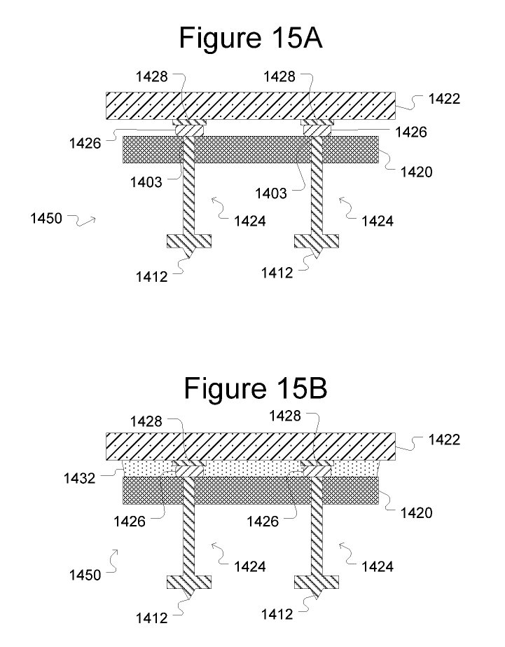

FIGS. 16A and 16B illustrate another example in which a plurality of probe array structures 1450 can be attached to an electronic component 1502 according to some embodiments of the invention. As shown in FIG. 16A, a plurality of probe array structures 1450 are soldered 1426 to terminals 1428 of electronic component 1502. As also shown in FIG. 16A, terminals 1428 are electrically connected to other terminals 1504 of electronic component 1502 by electrically conductive paths 1506 (e.g., conductive vias and traces through electronic component 1502). Electrical paths are thus provided from terminals 1504 to the tip features 1412 of probes 1424. As shown in FIG. 16B, which shows a bottom view of the structure of FIG. 16A, the plurality of probe array structures 1450 may be positioned on the electronic component 1502 to form a large array of probes 1424 comprising the probes 1424 of each of the probe array structures 1450.

U.S. Pat. No. 5,806,181 and U.S. Pat. No. 6,690,185 disclose additional information regarding attaching a substrate comprising probes to another substrate, and the techniques disclosed in those patents may be used in attaching a probe array structure (e.g., 216, 1250, 1350, or 1450) to another substrate (e.g., electronic components 1422,1502).

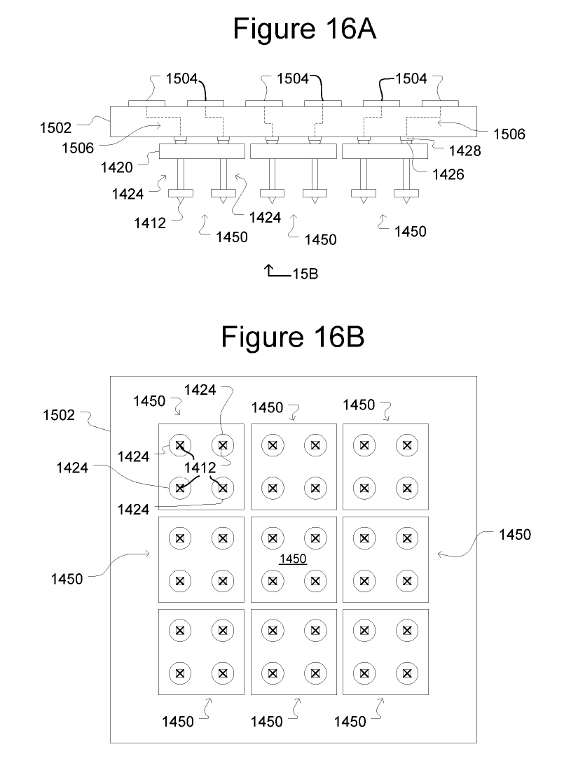

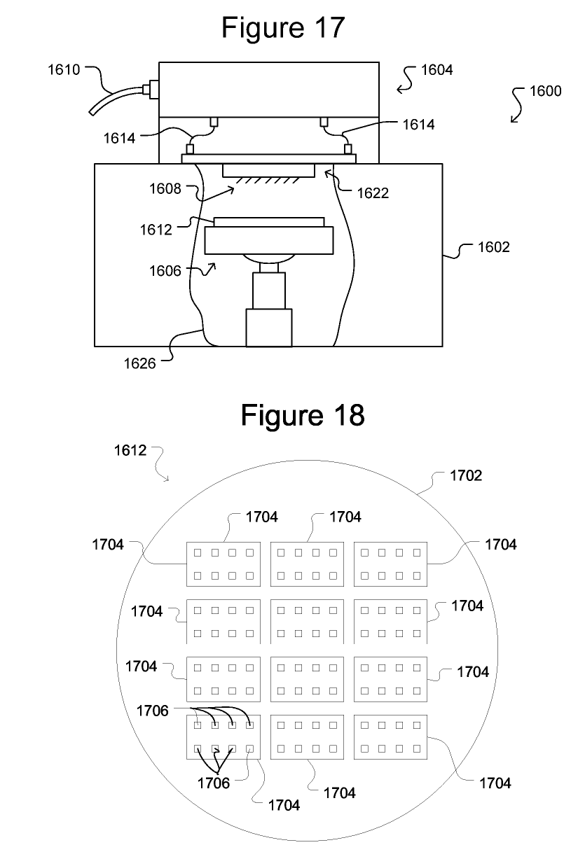

Whether one probe array structure 1450 (as shown in FIG. 15B) or a plurality of probe array structures 1450 (as shown in FIGS. 16A and 16B) are attached to an electronic component, one exemplary application for the resulting apparatus can be a probe head in a probe card assembly. FIG. 17 illustrates an exemplary semiconductor probing system 1600, that includes an exemplary probe card assembly 1622, for testing a semiconductor wafer like exemplary wafer 1612 shown in FIG. 18 according to some embodiments of the invention.

As shown, the probing system 1600 includes a test head 1604 and a prober 1602 (which is shown with a cut-away 1626 to provide a partial view of the inside of the prober 1602). To test one or more of the dies 1704 (see FIG. 18) of the semiconductor wafer 1612, the wafer 1612 is placed on a moveable stage 1606 as shown in FIG. 17, and the stage 1606 is moved such that input and/or output terminals 1706 (see FIG. 18) of dies 1704 are brought into contact with probes 1608 of probe card assembly 1622. Temporary electrical connections are thus established between probes 1606 and input and/or output terminals 1706 of the dies 1704 of the semiconductor wafer 1612.

As also shown in FIG. 17, a cable 1610 or other communication means connects a tester (not shown) with the test head 1604. Electrical connectors 1614 electrically connect the test head 1604 with the probe card assembly 1622, and the probe card assembly 1622 includes electrical paths (not shown in FIG. 17) to the probes 1608. Thus, while the probes 1606 are in contact with the terminals 1706 of the dies 1704, cable 1610, test head 1604, electrical connectors 1614, and probe card assembly 1622 provide a plurality of electrical paths between the tester (not shown) and the dies 1704. The tester (not shown) writes test data through these electrical paths to the dies 1704, and response data generated by the dies 1704 in response to the test data is returned to the tester through these electrical paths.

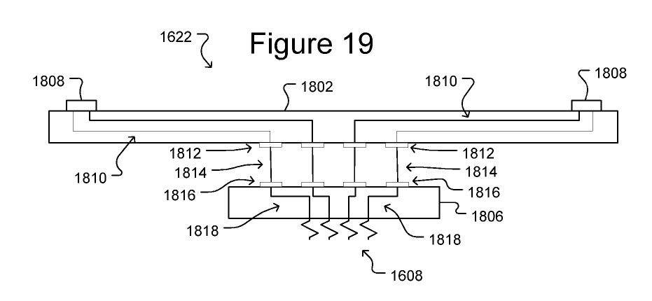

FIG. 19 shows a simplified block and schematic diagram of an exemplary probe card assembly 1622. The exemplary probe card assembly 1622 shown in FIG. 19 includes a circuit board 1802 with electrical connectors 1808 (e.g., zero-insertion-force connectors or pogo pin pads) for making electrical connections with connector 1614 of FIG. 17. The exemplary probe card assembly 1622 also includes a probe head 1806 with probes 1608 for contacting terminals 1706 of dies 1704 (see FIG. 18). Electrical connections 1810 (e.g., conductive vias and/or traces) through printed circuit board 1802 electrically connect connectors 1808 with terminals 1812. Likewise, electrical connections 1818 (e.g., conductive vias and/or traces) through probe head 1806 electrically connect terminals 1816 with probes 1608. Terminals 1812 and terminals 1816 are electrically connected by electrical connection means 1814, which may be any means for electrically connecting terminals 1812 and terminals 1816. For example, terminals 1816 may be soldered or brazed to terminals 1812, and connection means 1814 would thus comprise solder or brazing material. As another alternative, connection means 1814 may comprise an interposer like interposer 504 of FIG. 5 of U.S. Pat. No. 5,974,662 or multiple interposers like interposers 230 in FIG. 2 of U.S. Pat. No. 6,509,751. Probe head 1806 may be secured to circuit board 1802 using any suitable mechanisms, including without limitation brackets, screws, bolts, etc.

The probe head 1806 may be fabricated using any of the exemplary techniques disclosed above. For example, the probe head 1806 may be probe array structure 1250 of FIG. 13 with terminals 1816 (see FIG. 19) disposed over and electrically connected to finished ends 806 of probes 824 of probe array structure 1250. As another example, the probe head 1806 may be probe array structure 1350 of FIG. 14B with terminals 1816 (see FIG. 19) disposed over and electrically connected to distal ends 1306 of probes 1324 of probe array structure 1350. As yet another example, the probe head 1806 may be the structure shown in FIG. 15A or 14B with terminals 1816 (see FIG. 19) disposed on electronic component 1422 and electrical connections (not shown) through electronic component 1422 electrically connecting terminals 1816 (see FIG. 19) to terminals 1428. As still another example, the probe head 1806 may be the structure shown in FIGS. 16A and 16B. Terminals 1504 shown in FIG. 16A would take the place of terminals 1816 in FIG. 19.

In making a probe head using any of the techniques described herein, tip features of the probes are made to correspond to input and/or output terminals of the electronic device to be tested. Thus, for example, the pits 406—which define tip features 412 of probes 424—formed in sacrificial substrate 402 are positioned to correspond to a layout of input and/or output terminals of the electronic device to be tested. If the electronic device comprises dies of a semiconductor wafer like wafer 1702 of FIG. 18, the pits 406 are laid out on sacrificial substrate 402 to correspond to all or at least some of the input and/or output terminals 1706 of one or more of the dies 1704 of the wafer 1702. As mentioned above with respect to FIG. 4B, pits 406 can be positioned precisely and in tight pitches using lithographic processing techniques similar to those used to form integrated circuits in semiconductor materials. Pitches with separation of 150 microns or less between adjacent pits can be achieved. Thus, probe heads having probes (e.g., 424) with tip features (e.g., 411) spaced 150 microns or less apart can be made using the techniques disclosed in this application.

Although specific embodiments and applications of the invention have been described in this specification, there is no intention that the invention be limited these exemplary embodiments and applications or to the manner in which the exemplary embodiments and applications operate or are described herein. For example, the probes in any of the embodiments show in the figures may be replaced by other types of contact structures, including without limitation elongate, resilient contact structures.

What is claimed is:

1. A method of making a probe array structure, the method comprising:
providing a plurality of electrically conductive elongate contact structures having contact portions disposed on a first substrate; and
capturing base portions of the contact structures to form an aligned group of contact structures.

2. The method of claim 1, wherein the capturing comprises:
depositing a material on the first substrate partially encasing each of the contact structures, the base portions of each of the contact structures extending out of the material; and
disposing a second substrate around at least part of the base portions of the contact structures.

3. The method of claim 2, wherein the disposing comprises:
molding a flowable material around the at least part of the base portions of the contact structures;
hardening the flowable material to form the second substrate.

4. The method of claim 2, wherein the providing comprises forming the contact structures on the first substrate.

5. The method of claim 4, wherein the forming the contact structures on the first substrate comprises:
forming tips on the first substrate; and
forming elongate structures on the tips.

6. The method of claim 5, wherein the tips are patterned to correspond to bond pads of a semiconductor die.

7. The method of claim 6, wherein the forming tips comprises forming each tip less than 150 microns from an adjacent tip.

8. The method of claim 6, wherein the forming tips comprises depositing tip material in openings in a masking material deposited on the first substrate.

9. The method of claim 8, wherein the openings in the masking material expose pits in the first substrate that define features of the tips.

10. The method of claim 8, wherein the forming tips further comprises lithographically forming the openings in the masking material.

11. The method of claim 5, wherein the forming elongate structures comprises bonding wires to the tips.

12. The method of claim 11, wherein the forming elongate structures further comprises depositing at least one layer of material over the wires.

13. The method of claim 2, wherein the depositing comprises casting the material around the contact structures.

14. The method of claim 2, wherein the depositing comprises:
encasing an entire portion of all of the contact structures in the material; and
removing a portion of the material to expose the base portions of the contact structures.

15. The method of claim 14, wherein the depositing further comprises removing an outer portion of the material and ends of the contact structures encased in the outer portion of the material, wherein the removing an outer portion of the material is performed between the encasing and the removing a portion of the material to expose the base portions of the contact structures.

16. The method of claim 2 further comprising attaching the second substrate to a third substrate.

17. The method of claim 16, wherein the attaching comprises electrically connecting ones of the contact structures to electrically conductive terminals on the third substrate.

18. The method of claim 17, wherein contact portions of ones of the contact structures are disposed to contact conductive terminals of a semiconductor die, and the third substrate is part of a probe card assembly configured to provide an interface for testing the die.

19. The method of claim 2, wherein the second substrate and the plurality of contact structures compose the probe array structure, and the method further comprises performing the providing and the capturing a plurality of times to make a plurality of the probe array structures.

20. The method of claim 19 further comprising attaching the plurality of probe array structures to a third substrate, wherein contact portions of ones of the contact structures of the plurality of probe array structures are disposed in a pattern corresponding to terminals of electronic devices to be tested.

21. The method of claim 20, wherein the attaching comprises electrically connecting ones of the contact structures of the plurality of probe array structures to electrically conductive terminals on the third substrate.

22. The method of claim 21, wherein the electronic devices are semiconductor dies, and the third substrate is part of a probe card assembly configured to provide an interface for testing the dies.

23. The method of claim 2, wherein:
the depositing comprises:
encasing the contact structures in the material, and
removing a portion of the material to expose the base portions of the contact structures;
the disposing comprises:
molding a flowable material around the at least part of the base portions of the contact structures, and
hardening the flowable material to form the second substrate; the method further comprising:
freeing the contact structures from the securing material and the first substrate;
wherein contact portions of ones of the contact structures are disposed to correspond to conductive terminals of at least a portion of at least one electronic device to be tested.

24. A probe array structure comprising
a plurality of elongate, electrically conductive contact structures; and
a substrate comprising a moldable material molded around portions of the contact structures and hardened to embed the portions of the contact structures in the hardened material,
wherein each contact structure passes through the substrate providing an electrically conductive path from a first end of the contact structure disposed to a first side of the substrate to a second end of the contact structure disposed to a second, opposite side the substrate.

25. The probe array structure of claim 24, wherein the first ends of the contact structures comprise tips disposed to correspond to terminals of at least a portion of an electronic device.

26. The probe array structure of claim 25, wherein each of the tips is disposed less than 150 microns from an adjacent tip.

27. The probe array structure of claim 26, wherein each of the contact structures comprises an elongate structure a portion of which is embedded in the substrate and a structurally distinct tip, and the tip is bonded to the elongate structure.

28. The probe array structure of claim 27, wherein each elongate structure comprises a wire that is wire bonded to a corresponding tip.

29. The probe array structure of claim 29, wherein each wire is bonded to a corresponding tip without solder or brazing material.
